(19) United States
(12) Patent Application Publication
(10) Pub. No.: US 2010/0098971 A1
(43) Pub. Date: Apr. 22, 2010

(54) COATING FOR GAS TURBINE COMPONENTS, AND METHOD AND DEVICE FOR PROVIDING A COATING

(76) Inventors: Horst Pillhoefer, Roehmoos (DE); Heinrich Walter, Friedberg (DE); Markus Niedermeier, Muenchen (DE); Joern Kohlscheen, Bremen (DE)

Correspondence Address: CROWELL & MORING LLP;INTELLECTUAL PROPERTY GROUP, P.O. BOX 14300, WASHINGTON, DC, 20044-4300, US

(21) Appl. No.: 12/527,823

(22) PCT Filed: Feb. 14, 2008
(86) PCT No.: PCT/DE08/00280

§ 371 Date: Aug. 19, 2009

(30) Foreign Application Priority Data
Feb. 20, 2007 (DE) 10 2007 008 278.0

(51) Int. Cl. B32B 15/01; C23C 16/08; C23C 10/48; C23C 10/52

(52) U.S. Cl. 428/680; 427/248.1; 427/255.7; 118/715

(57) ABSTRACT

A coating, in particular for gas turbine components produced of a superalloy, is disclosed. The coating has an outer layer and an inner layer. The outer layer constitutes 10% to 60% of the overall coating and is substantially made of a β-NiAl phase having an Al proportion between 23 and 35 percent by weight. The inner layer constitutes 90% to 40% of the overall coating and is substantially made of a γ-NiAl phase having an Al proportion of a maximum of 15 percent by weight.

This application claims the priority of International Application No. PCT/DE2008/000280, filed Feb. 14, 2008, and German Patent Document No. 10 2007 008 278.0, filed Feb. 20, 2007, the disclosures of which are expressly incorporated by reference herein.

### BACKGROUND AND SUMMARY OF THE INVENTION

The invention relates to a coating. In addition, the invention relates to a method for providing a coating as well as a device for providing a coating.

The most important materials used nowadays for gas turbine components are titanium-based alloys, superalloys and high-strength steels. Nickel-based alloys and cobalt-based alloys should be understood as superalloys. High strength steels are used for shaft parts, gear parts, the compressor housing and turbine housing of a gas turbine. Titanium-based alloys are the typical materials for compressor parts. Superalloys are suitable for the hot parts of a gas turbine and thus for high-temperature applications.

When used in gas turbines, components made of superalloys are exposed to temperatures of more than 1000° C., high stress from centrifugal forces as well as stress from fluctuations in temperature. Superalloys used for gas turbine components are typically designed for a good combination of temperature resistance, creep resistance and resilience to changes in tensile strain. This is accomplished by selecting suitable alloy elements and by using materials that are solidified directionally or monocrystallinely.

However, the measures that are used to increase the strength of a material typically lead to greater susceptibility of surfaces and boundary layers to hot gas oxidation and hot gas corrosion. As a result, gas turbine components are provided with protective layers in order to protect the components from hot gas oxidation and hot gas corrosion.

Diffusion coating methods and layer coating methods are known first and foremost from practice as coating methods for applying protective coatings to gas turbine components. Diffusion coatings are based on an inter-diffusion of deposited elements of the coating material with elements of the superalloy of the component being coated, wherein diffusion coating methods are subdivided into high activity diffusion coating methods and low activity diffusion coating methods.

In the case of high activity diffusion coating methods, a high inward diffusion of the coating material in the material of the component being coated takes place. One the other hand, in the case of low activity diffusion coating methods, a stronger outward diffusion of elements of the material of the component being coated occurs in the coating material of the coating being deposited. Layer coating methods are based less on an inter-diffusion; in fact the protective effect of the coating is an inherent property of the deposited material or the deposited material particles.

Coating methods known from practice have only a low deposition capacity. In addition, it is difficult to coat internal surfaces, such as, for example, inner geometries of hollow components, with the coating methods that have been known so far. Coatings known until now are highly susceptible to cracking on exterior zones, thereby restricting the service life of known coatings. As a result, there is a need for new coatings with a longer service life, for a method for producing such coatings with a higher deposition capacity as well as for a device for producing such a coating.

Starting herefrom, the objective of the present invention is creating a novel coating as well as a method and device for providing a coating.

According to the invention, the outer layer constitutes 10% to 60% of the overall coating, wherein the outer layer is substantially made of a β-NiAl phase having an Al proportion between 23 and 35 percent by weight, wherein the inner layer constitutes 90% to 40% of the overall coating, and wherein the inner layer is substantially made of a γ-NiAl phase having an Al proportion of a maximum of 15 percent by weight.

The inventive coating has relatively low susceptibility to cracking as well as good resistance in the case of high cycle fatigue (HCF) load and low cycle fatigue (LCF) load. The inventive coating provides effective protection of gas turbine components from hot gas oxidation and hot gas corrosion.

The Al proportion in the β-NiAl phase of the outer layer is preferably between 27 and 32 percent by weight and the Al proportion in the γ-NiAl phase of the inner layer preferably is between 5 and 15 percent by weight.

According to a further development of the invention, the β-NiAl phase of the outer layer also includes Cr and/or Si and/or Pt and/or Pd.

According to a method of the invention, a pressure of between 30 and 1,400 hPa is adjusted during an initial phase of the coating process, wherein, during the initial phase, at least metal monohalides are formed from at least one provided halogen or at least one provided halogen compound and at least one provided donor metal, in particular from a provided donor metal alloy, wherein a pressure of between 1,050 and 4,000 hPa is adjusted during a coating phase of the coating process following the initial phase, and wherein the metal monohalides formed during the initial phase are deposited on the component being coated during the coating phase.

The inventive coating method is characterized by a high deposition capacity. Using the inventive coating method, exterior surfaces, on the one hand, and interior surfaces of the to-be-coated components can be coated equally well.

According to a device of the invention, the components to be coated and the donors are arranged in the reaction chamber spaced apart from one another on parallel levels such that the distance between the components to be coated and the donors is between 10 and 150 mm.

The inventive device makes an effective as well as economical coating of the to-be-coated components possible.

Preferred further developments of the invention are disclosed in the following specification. Without being limited hereto, exemplary embodiments of the invention are explained in greater detail on the basis of the drawing.

### BRIEF DESCRIPTION OF THE DRAWING

FIG. 1 is a schematic device for providing a coating.

### DETAILED DESCRIPTION OF THE DRAWING

The present invention relates to a new coating for gas turbine components, in particular for gas turbine components produced of a superalloy, for providing a protective layer against hot gas oxidation as well as hot gas corrosion. In addition, the invention relates to a method as well as a device for producing such a coating.

The inventive coating has an outer layer as well as an inner layer. The outer layer of the inventive coating constitutes between 10% and 60% of the overall coating, wherein the outer layer is substantially made of a β-NiAl phase having a proportion of aluminum (Al) of between 23 and 35 percent by weight. The Al proportion in the β-NiAl phase of the outer layer is preferably between 27 and 32 percent by weight.

The inner layer of the overall coating constitutes between 90% to 40% of the overall coating, wherein the inner layer is substantially made of a γ-NiAl phase with a proportion of aluminum of a maximum of 15 percent by weight. The Al proportion in the γ-NiAl phase of the inner layer is in particular between 5 and 15 percent by weight.

The good protective property against hot gas oxidation and hot gas corrosion of the inventive coating is provided by the relatively high proportion of aluminum in the outer layer from the β-NiAl phase. The low susceptibility to cracking of the inventive coating is guaranteed by the γ-NiAl phase of the inner layer with the relatively low proportion of aluminum. The inner layer is preferably characterized by a cubic γ or γ′ crystal lattice corresponding to the crystal lattice structure of the base material of the component being coated.

A further increase in the oxidation resistance as well as corrosion resistance of the inventive coating can be achieved in that the outer layer of the inventive coating comprises chromium and/or silicon and/or platinum and/or palladium.

When the outer layer includes chromium, the chromium proportion in the outer layer is preferably between 10 and 35 percent by weight, in particular between 20 and 30 percent by weight. When the outer layer includes silicon, the proportion of silicon is between 2 and 14 percent by weight, in particular between 4 and 9 percent by weight. When the outer layer includes platinum and/or palladium, the proportion of platinum and/or palladium is between 10 and 40 percent by weight.

The inventive method for providing the inventive coating is subdivided into at least two phases, namely into an initial phase as well as a coating phase following the initial phase.

A pressure of between 30 and 1,400 hPa is adjusted during the initial phase of the coating process, wherein, during the initial phase, at least metal monohalides are formed from at least one provided halogen or at least one provided halogen compound and at least one provided donor metal, in particular from a provided donor metal alloy.

Chlorine (Cl) or fluorine (Fl) are preferably provided as halogens, and/or hydrogen chloride (HCl) or hydrogen fluoride (HF) are preferably provided as halogen compounds. Metal monohalides are formed from the halogens or halogen compounds and the donor material.

During the initial phase of the coating process both halogen compounds MeHal as well as monohalides MeHal occur during the gas phase according to the following equation:

MeₓHal_{y}+zMe [symbol] MeHal; x, z=1-2 and y=2-3.

As a result, a relatively low pressure of between 20 and 1,400 hPa is adjusted during the initial phase in order to provide a higher proportion of metal monohalides during the gas phase.

The coating phase, in which a relatively high pressure of between 1,050 and 4,000 hPa is adjusted, follows the initial phase of the coating process. The metal monohalides formed during the initial phase are deposited on the surface of the component being coated during the coating phase, wherein in this case the metal monohalides react in a so-called decomposition reaction or disproportion reaction with the base material of the component being coated according to the following equations:

MeHal+Ni [symbol] NiMe+MeₓHal_{y}; x=2-4 and y=1-3

or

MeHal+Ni [symbol] MeHal+Hal.

Consequently, in terms of the inventive method, metal monohalides are provided with relatively low pressure of between 30 and 1,400 hPa during an initial phase and the metal monohalides provided during the initial phase are deposited in a subsequent coating phase with a relatively high pressure of between 1,050 and 4,000 hPa on the surface of the component being coated.

By using the relatively high pressure of between 1,050 and 4,000 hPa during the coating phase, the relative proportion of metal halides in the gas phase can be increased around the component surface. On the other hand, the relatively high pressure during the coating phase results in a considerably higher proportion of metal deposition on the surface of the component being coated. A further advantage of the relatively high pressure during the coating phase of the inventive method is an increased throwing power, i.e., the distance of the donor material from the surface of the component being coated can be greater with the same activity, thereby making it possible to realize more uniform deposition or coating of the component being coated. In addition, because of the increased throwing power, internal surfaces of the component being coated, in particular inner geometries of cavities, can be coated well. A further advantage of the relatively high pressure during the coating phase is the long-lasting preservation of a metal halide activator. Thus, higher activator availability is produced as well as a higher activator holding time without additional halogens or halogen compounds having to be introduced. As a result, it is possible to coat for a longer period with greater deposition capacity.

According to an advantageous further development of the inventive coating method, a reaction phase with a pressure of between 500 and 1,400 hPa follows the coating phase, wherein a further coating phase with a pressure of between 1,050 and 4,000 hPa follows this reaction phase. As a result, the deposition capacity of the inventive coating method can again be raised or increased.

Because of the alternating phases with relatively high pressures and relatively low pressures, a type of thermo-chemical pump is made available for forming the metal monohalides, which ultimately contributes to the good deposition capacity of the inventive coating method.

The initial phase preferably extends over a duration of time of between 5 and 60 min., the coating phase following the initial phase preferably extends over a duration of time of between 10 and 120 min. A reaction phase, if applicable, following the coating phase extends between 5 and 60 min., and a further coating phase, if applicable, following this extends in particular between 10 and 120 min.

The inventive method is conducted at a processing temperature of between 900° and 1150° C., in particular at a processing temperature of between 940° and 1080° C.

In this case, the temperature during the or each coating phase is preferably between 10° and 60° higher than the temperature of the respectively preceding phase, i.e., the initial phase or the reaction phase. As a result, it is possible to generate defined diffusion profiles as a function of the different metal deposition activities in the various phases of the process.

The donor metal is preferably provided with a particle size of between 2 and 20 mm, wherein the halogen or the halogen compound is directed directly to the donor material. In doing so, the halogen or the halogen compound preferably flows around the donor material at a flow speed of between 0.1 and 10 cm per second.

Aluminum in particular is deposited in the above manner on the component being coated.

The alloying of the elements chromium, silicon, platinum and/or palladium preferably takes place by a pre-alloying of the outer layer with a thermal, thermo-chemical or physical method or by subsequent diffusing, wherein the pre-alloying is preferred.

An over-aluminizing of a coating layer of particles of the elements chromium, silicon, platinum and/or palladium or particles of an alloy with these elements can produce the inventive coating.

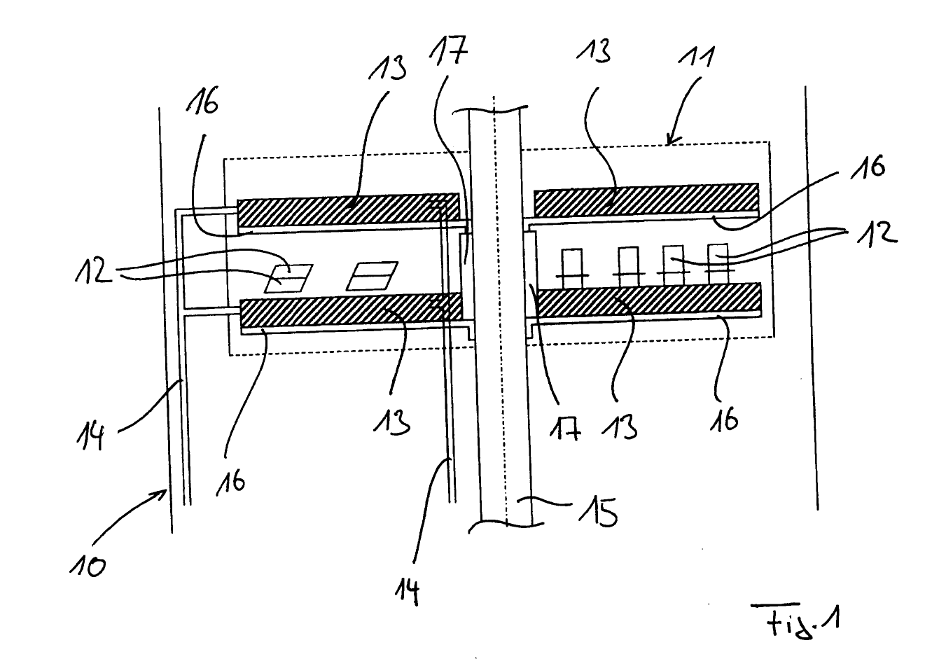

The inventive method for providing the inventive coating is conducted in a special device, which makes possible an economic coating of the to-be-coated components. FIG. 1 shows a very schematized depiction of such a coating device 10.

Thus, the inventive coating device 10 has a reaction chamber 11 for accommodating the components 12 to be coated and for accommodating donors 13 made of at least one donor metal, in particular a donor metal alloy. In this case, the donors 13 according to FIG. 1 are arranged spaced apart from one another on levels running parallel to one another, wherein components 12 to be coated are positioned between respectively two adjacent levels of donors 13. The exemplary embodiment in FIG. 1 only depicts two levels of donors 13. Up to ten levels of donors 13 can be positioned on top of one another in the reaction chamber 11.

As already stated, the components 12 to be coated are arranged between respectively two levels of donors 13 and namely in such a way the distance between the components 12 to be coated and the donors 13 is between 10 and 150 mm, preferably between 20 and 150 mm.

The reaction chamber is preferably configured to be rotationally symmetrical with a diameter of between 200 and 1,500 mm and a height of up to 1,500 mm, wherein the volumetric density of the donors 13 as related to the total volume of the reaction chamber 11 is between 2% and 5%.

Halogens or halogen compounds can be conveyed via feed lines 14 in the direction of the donors 13, namely in such a way that the halogens or halogen compounds are directed directly to the donors 13, namely solid particles of the or each donor metal. In this case, as FIG. 1 shows, the feed lines 14 are introduced into the reaction chamber 11 from the radial outside, on the one hand, as well as, on the other hand, from the radial inside.

The inventive coating device 10 has a center pipe 15, on which several cross members 16 engage. The cross members 16 are used to accommodate the donors 13, wherein cross members 16 arranged above one another are spaced apart by spacers 17.

The cross members 16 are preferably segmented as viewed in the circumferential direction, and namely with an angle division of between 22.5° and 60°. Consequently, as viewed in the circumferential direction, each cross member 16 is divided into six to sixteen segments, wherein each segment is used to accommodate donors 13.

The inventive device is designed with a modular structure and allows expansion with regard to the effects of both temperature and alloying.

As already mentioned, the halogens or halogen compounds are not introduced openly into the reaction chamber 11, but directed via feed lines 14 directly to the donors 13. The donors can be designed to be tightly closed or in an open-cell design, with an opening proportion of between 5% and 80%. As already mentioned, the donors 13 are preferably segmented per level with a defined angle division. It is also possible to arrange several ring-like donor segments concentrically with one another for each donor level.

1-21. (canceled)

22. A coating, in particular for gas turbine components produced of a superalloy, comprising:
a) an outer layer, wherein the outer layer constitutes 10% to 60% of the coating and wherein the outer layer is substantially made of a β-NiAl phase having an Al proportion between 23 and 35 percent by weight; and
b) an inner layer, wherein the inner layer constitutes 90% to 40% of the coating and wherein the inner layer is substantially made of a γ-NiAl phase having an Al proportion of a maximum of 15 percent by weight.

23. The coating according to claim 22, wherein the Al proportion in the β-NiAl phase of the outer layer is between 27 and 32 percent by weight.

24. The coating according to claim 22, wherein the outer layer includes Cr in a proportion between 10 and 35 percent by weight.

25. The coating according to claim 22, wherein the outer layer includes Si in a proportion between 2 and 14 percent by weight.

26. The coating according to claim 22, wherein the outer layer includes Pt and/or Pd in a proportion between 10 and 40 percent by weight.

27. The coating according to claim 22, wherein the Al proportion in the γ-NiAl phase of the inner layer is between 5 and 15 percent by weight.

28. The coating according to claim 22, wherein the coating is applied to a gas turbine component made of a superalloy.

29. A method for providing a coating as a gas phase coating, comprising the steps of:
a) adjusting a pressure of between 30 and 1,400 hPa during an initial phase of the coating process, wherein, during the initial phase, at least metal monohalides are formed from at least one provided halogen or from at least one provided halogen compound and at least one provided donor metal; and
b) adjusting a pressure of between 1,050 and 4,000 hPa during a coating phase following the initial phase, wherein the metal monohalides formed during the initial phase are deposited on a component being coated during the coating phase.

30. The method according to claim 29, wherein the initial phase is conducted for a duration of time of between 5 and 60 minutes and the coating phase for a duration of time of between 10 and 120 minutes.

31. The method according to claim 29, wherein during the initial phase, hydrogen chloride and/or hydrogen fluoride is directed to the donor metal as the halogen compound.

32. The method according to claim 29, wherein the donor metal is provided with a particle size of between 2 and 20 mm, and that the halogen or the halogen compound is directed directly to the donor metal such that the halogen or the halogen compound flows around the donor metal at a flow speed of between 0.1 to 10 cm/sec.

33. The method according to claim 29, further comprising the step of adjusting a pressure of between 500 and 1,400 hPa during a reaction phase following the coating phase, wherein the reaction phase is conducted for a duration of time of between 5 and 60 minutes.

34. The method according to claim 33, further comprising a further coating phase following the reaction phase, wherein a pressure of between 1,050 and 4,000 hPa is adjusted, and wherein the further coating phase is performed for a duration of time of between 10 and 120 minutes.

35. The method according to claim 29, wherein the method is conducted at a processing temperature of between 900 and 1150° C.

36. The method according to claim 29, wherein a temperature of the coating phase is between 10 and 60° C. higher than a temperature of the initial phase.

37. A device for providing a coating, comprising:
a reaction chamber, wherein components to be coated and donors made of at least one donor metal are disposed within the reaction chamber;
and wherein the components to be coated and the donors are arranged in the reaction chamber spaced apart from one another on parallel levels such that a distance between the components to be coated and the donors is between 10 and 150 mm.

38. The device according to claim 37, wherein the distance between the components to be coated and the donors is between 20 and 150 mm.

39. The device according to claim 37, wherein several components to be coated are respectively arranged between two respective levels of donors arranged above one another, wherein up to ten donor levels are arranged in the reaction chamber.

40. The device according to claim 37, wherein the reaction chamber is configured to be rotationally symmetrical with a diameter of between 200 and 1,500 mm and a height of up to 1,500 mm.

41. The device according to claim 37, wherein a volumetric density of the donors as related to a volume of the reaction chamber is between 2% and 5%.

42. A device according to claim 37, wherein at least one halogen compound can be directed to the donors via feed lines.
